(19) United States
(12) Patent Application Publication
(10) Pub. No.: US 2017/0301658 A1
(43) Pub. Date: Oct. 19, 2017

(54) FABRICATION METHOD OF PACKAGE STRUCTURE

(71) Applicant: Siliconware Precision Industries Co., Ltd., Taichung (TW)

(72) Inventors: Yu-Cheng Pai, Taichung (TW); Chun-Hsien Lin, Taichung (TW); Shih-Chao Chiu, Taichung (TW); Wei-Chung Hsiao, Taichung (TW); Ming-Chen Sun, Taichung (TW); Tzu-Chieh Shen, Taichung (TW); Chia-Cheng Chen, Taichung (TW)

(21) Appl. No.: 15/636,217

(22) Filed: Jun. 28, 2017

Related U.S. Application Data
(62) Division of application No. 14/562,972, filed on Dec. 8, 2014.

(30) Foreign Application Priority Data
Jul. 11, 2014 (TW) 103123899

(51) Int. Cl. H01L 25/10; H01L 21/48; H01L 23/13; H01L 23/498; H01L 23/00; H01L 23/538; H01L 25/00

(52) U.S. Cl. CPC H01L 25/105; H01L 23/5389; H01L 21/486; H01L 23/13; H01L 23/49811; H01L 25/50; H01L 24/16; H01L 21/4857; H01L 23/49838; H01L 23/49827; H01L 23/49822; H01L 2224/16227; H01L 2225/1023; H01L 2225/1058; H01L 2924/15153

(57) ABSTRACT

A method for fabricating a package structure is provided, which includes the steps of: providing a carrier having a plurality of bonding pads; laminating a dielectric layer on the carrier; forming a plurality of conductive posts in the dielectric layer; and forming a cavity in the dielectric layer to expose the bonding pads, wherein the conductive posts are positioned around a periphery of the cavity, thereby simplifying the fabrication process.

### BACKGROUND OF THE INVENTION

### 1. Field of the Invention

The present invention relates to package structures and fabrication methods thereof, and more particularly, to a package structure and a fabrication method thereof having simplified processes.

### 2. Description of Related Art

Along with the progress of semiconductor packaging technologies, various package types have been developed for semiconductor devices. To improve electrical performances and save spaces, a plurality of packages can be stacked to form a package on package (PoP) structure. Such a packaging method allows merging of heterogeneous technologies in a system-in-package (SiP) so as to systematically integrate a plurality of electronic elements having different functions, such as a memory, a CPU (Central Processing Unit), a GPU (Graphics Processing Unit), an image application processor and so on, and therefore is applicable to various thin type electronic products.

Generally, to form a PoP structure, at least two packages are stacked on one another and electrically connected through a plurality of solder balls. However, as the packages tend to have smaller sizes and fine pitches, solder bridging easily occurs between the solder balls, thus adversely affecting the product yield.

Accordingly, copper pillars are formed to achieve a stand-off effect and prevent solder bridging. FIGS. 1A and 1B are schematic cross-sectional views showing a method for fabricating a PoP structure 1 according to the prior art.

Referring to FIG. 1A, a first substrate 11 having a first surface 11a with a plurality of copper pillars 13 and a second surface 11b opposite to the first surface 11a is provided.

Referring to FIG. 1B, an electronic element 15 is disposed on the first surface 11a and electrically connected to the first substrate 11 in a flip-chip manner. Then, a second substrate 12 is stacked on the first substrate 11 through the copper pillars 13. In particular, the second substrate 12 is bonded to the copper pillars 13 through a plurality of conductive elements 17. Each of the conductive elements 17 consists of a metal pillar 170 and a solder material 171 formed on the metal pillar 170. Subsequently, an encapsulant 16 is formed between the first surface 11a of the first substrate 11 and the second substrate 12.

However, since the copper pillars 13 are formed by electroplating, the size of the copper pillars 13 is difficult to control and the copper pillars 13 tend to have uneven heights. As such, a positional deviation easily occurs to the joints between the conductive elements 17 and the copper pillars 13 and hence a poor bonding easily occurs therebetween, thereby reducing the electrical performance and the product yield of the PoP structure 1.

Therefore, there is a need to provide a package structure and a fabrication method thereof so as to overcome the above-described drawbacks.

### SUMMARY OF THE INVENTION

In view of the above-described drawbacks, the present invention provides a package structure, which comprises: a carrier having a plurality of bonding pads; a dielectric layer having opposite first and second surfaces and formed on the carrier via the first surface thereof, wherein at least a cavity is formed in the second surface of the dielectric layer to expose the bonding pads; and a plurality of conductive posts formed in the dielectric layer and positioned around a periphery of the cavity.

The present invention further provides a method for fabricating a package structure, which comprises the steps of: providing a carrier having a plurality of bonding pads and a dielectric layer having opposite first and second surfaces; laminating the dielectric layer on the carrier via the first surface thereof, wherein the bonding pads are covered by the dielectric layer; forming a plurality of conductive posts in the dielectric layer; and forming at least a cavity in the second surface of the dielectric layer so as to expose the bonding pads, wherein the conductive posts are positioned around a periphery of the cavity.

In the above-described method, the second surface of the dielectric layer can have a conductive layer used for forming the conductive posts.

In the above-described method, forming the conductive posts can comprise: forming a plurality of through holes penetrating the dielectric layer; and filling a conductive material in the through holes to form the conductive posts.

The above-described method can further comprise stacking a stack member on the second surface of the dielectric layer, wherein the stack member is electrically connected to the conductive posts. The stack member can be a packaging substrate, a semiconductor chip, an interposer or a package.

In the above-described structure and method, the carrier can be a packaging substrate, a semiconductor chip, a wafer, an interposer, or a packaged or unpackaged semiconductor element.

In the above-described structure and method, a circuit layer can be formed on the second surface of the dielectric layer and electrically connected to the conductive posts.

In the above-described structure and method, the dielectric layer can be made of a photo imageable dielectric material. As such, the cavity can be formed by exposure and development.

The above-described structure and method can further comprise disposing an electronic element in the cavity, wherein the electronic element is electrically connected to the bonding pads.

According to the present invention, a dielectric layer is laminated on a carrier and a plurality of conductive posts are formed in the dielectric layer so as to achieve a preferred stand-off effect and prevent bridging from occurring between the conductive posts.

Further, the size of the conductive posts can be controlled through the through holes so as to cause the conductive posts to have a uniform height. Therefore, the present invention overcomes the conventional drawback of joint deviation and ensures a reliable bonding between the conductive posts and the conductive elements to be formed later, thereby improving the product yield.

### BRIEF DESCRIPTION OF DRAWINGS

FIGS. 1A and 1B are schematic cross-sectional views showing a method for fabricating a PoP structure according to the prior art; and

FIGS. 2A to 2G are schematic cross-sectional views showing a method for fabricating a PoP structure according to the present invention.

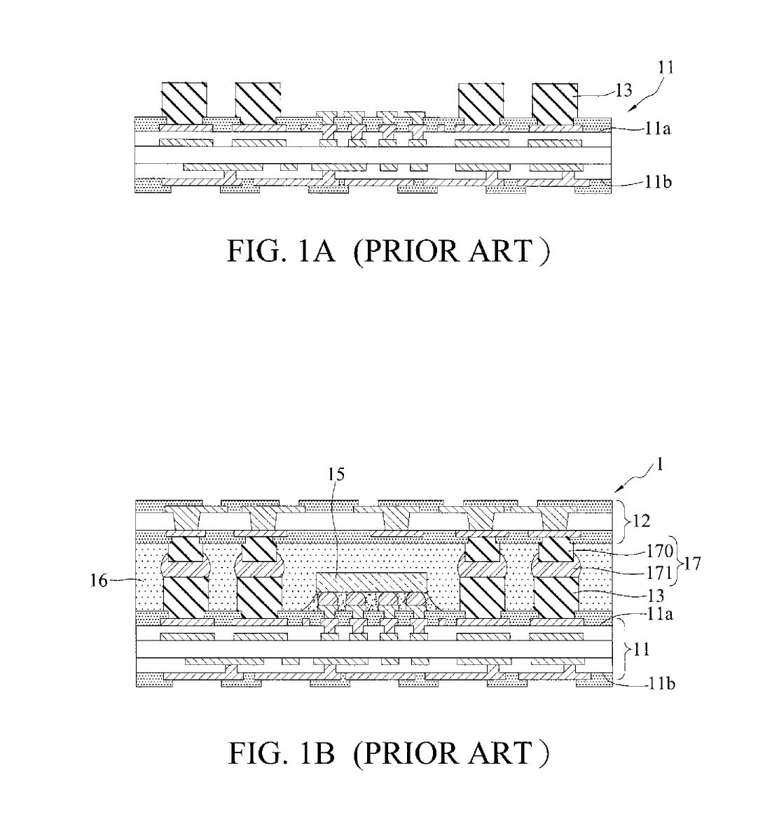

### DETAILED DESCRIPTION OF PREFERRED EMBODIMENTS

The following illustrative embodiments are provided to illustrate the disclosure of the present invention, these and other advantages and effects can be apparent to those in the art after reading this specification.

It should be noted that all the drawings are not intended to limit the present invention. Various modifications and variations can be made without departing from the spirit of the present invention. Further, terms such as “first”, “second”, “on”, “a” etc. are merely for illustrative purposes and should not be construed to limit the scope of the present invention.

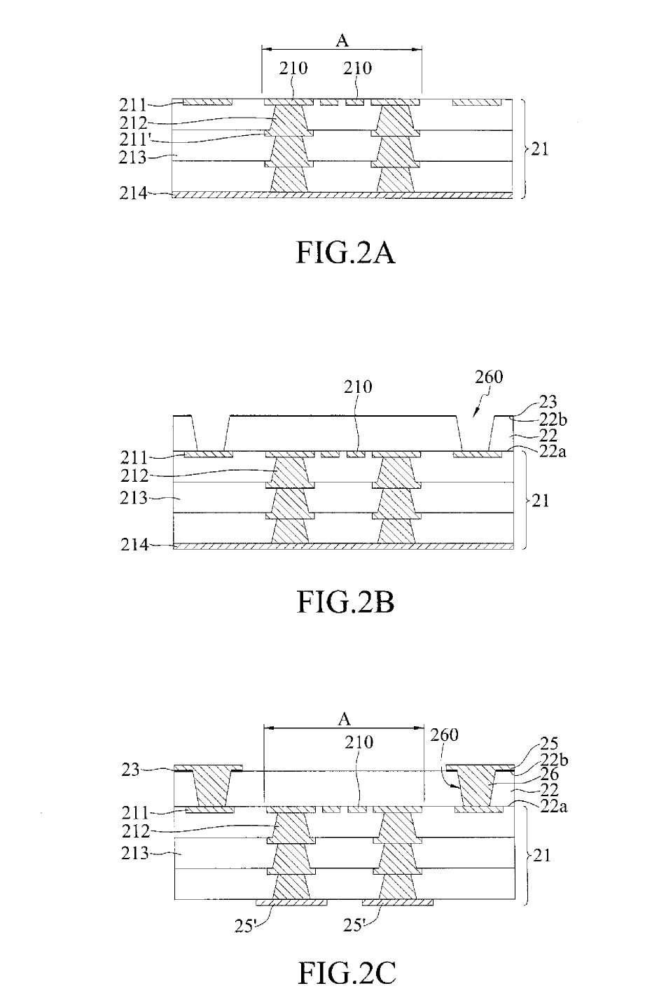

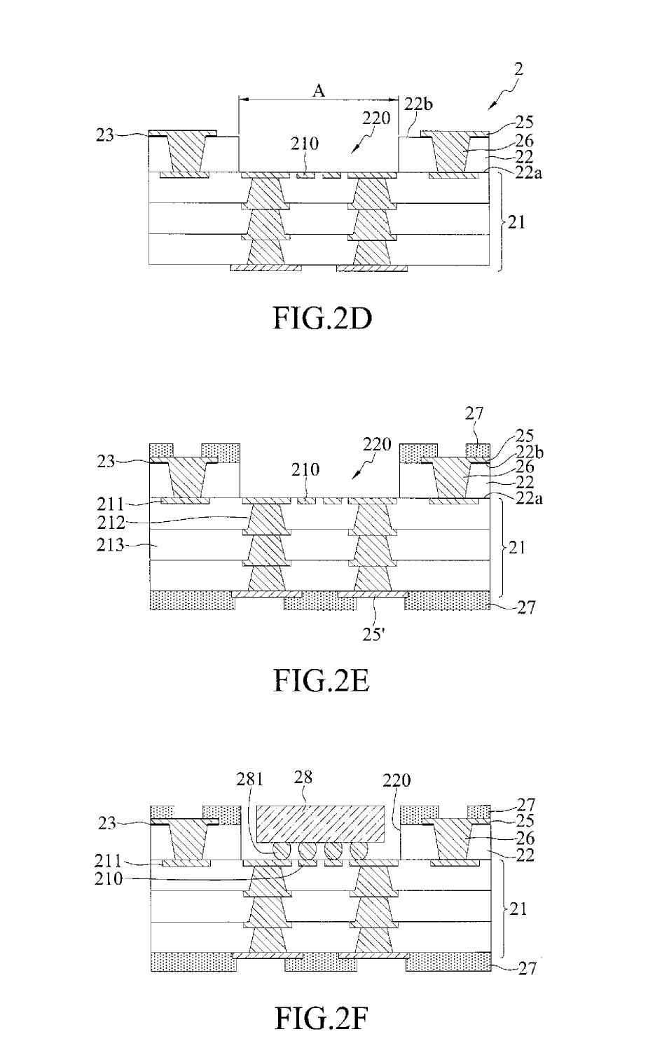

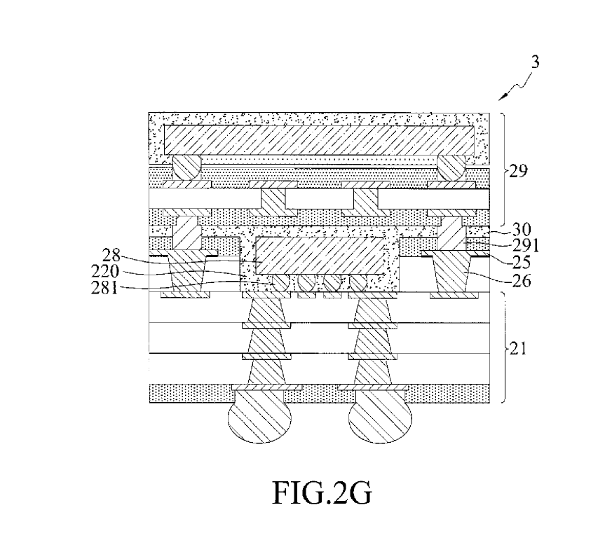

FIGS. 2A to 2G are schematic cross-sectional views showing a method for fabricating a package structure according to the present invention.

Referring to FIG. 2A, a carrier 21 having a plurality of first bonding pads 210 and a plurality of second bonding pads 211 is provided.

In the present embodiment, the carrier 21 is a packaging substrate, a semiconductor chip, a wafer, an interposer, or a packaged or unpackaged semiconductor element. For example, referring to FIG. 2A, the carrier 21 is a coreless packaging substrate, which has a plurality of dielectric layers 213 and a plurality of circuit layers 211′ alternately stacked on one another and a plurality of conductive vias 212 penetrating the dielectric layers 213 and electrically connected to the circuit layers 211′. Further, a metal layer 214 made of such as copper is formed on a lower side of the carrier 21.

A carrying area A is defined on the carrier 21. The first bonding pads 210 are positioned inside the carrying area A and the second bonding pads 211 are positioned outside the carrying area A.

Referring to FIG. 2B, a dielectric layer 22 having a conductive layer 23 thereon is laminated on the carrier 21 to cover the first and second bonding pads 210, 211. Then, by performing a laser drilling process, a plurality of through holes 260 are formed to penetrate the dielectric layer 22 and the conductive layer 23 corresponding in position to the second bonding pads 211.

In the present embodiment, the dielectric layer 22 has opposite first and second surfaces 22a, 22b. The conductive layer 23 is formed on the second surface 22b of the dielectric layer 22, and the dielectric layer 22 is laminated on the carrier 21 via the first surface 22a thereof.

Further, the dielectric layer 22 is made of a photo imageable dielectric (PID) material and the conductive layer 23 is a copper layer.

By laminating the dielectric layer 22 on the carrier 21, the present invention simplifies the fabrication process.

Referring to FIG. 2C, by using the conductive layer 23 as a conductive path, a circuit layer 25 is formed on the second surface 22b of the dielectric layer 22 and a conductive material is filled in the through holes 260 to form a plurality of conductive posts 26 electrically connecting the circuit layer 25 and the second bonding pads 211.

In the present embodiment, the circuit layer 25 is not formed on the second surface 22b of the dielectric layer 22 corresponding in position to the carrying area A.

Further, the metal layer 214 on the lower side of the carrier 21 is patterned to form a circuit layer 25′.

Referring to FIG. 2D, by performing an exposure and development process, a cavity 220 is formed in the second surface 22b of the dielectric layer 22 to expose the first bonding pads 210. The conductive posts 26 are positioned around a periphery of the cavity 220. As such, a package structure 2 is formed.

In the present embodiment, an upper side of the carrier 21 in the carrying area A is also exposed from the cavity 220.

Referring to FIG. 2E, an insulating layer 27 is formed on the second surface 22b of the dielectric layer 22 and the lower side of the carrier 21, and portions of the circuit layers 25, 25′ are exposed from the insulating layer 27 for mounting external elements in subsequent processes.

Referring to FIG. 2F, at least an electronic element 28 is disposed in the cavity 220 and electrically connected to the first bonding pads 210 through a plurality of conductive bumps 281.

Referring to FIG. 2G, a stack member 29 is stacked on the exposed portions of the circuit layer 25 and covers the cavity 220 and the electronic element 28. As such, a package structure 3 is formed.

In the present embodiment, the stack member 29 is a packaging substrate, a semiconductor chip, a wafer, a silicon interposer or a package. The stack member 29 is electrically connected to the circuit layer 25 and the conductive posts 26 through a plurality of conductive elements 291 made of such as a solder material or metal posts.

Further, an encapsulant 30 is formed between the stack member 29 and the carrier 21 for encapsulating the conductive bumps 281.

The present invention further provides a package structure 2, which has: a carrier 21 having a plurality of bonding pads 210; a dielectric layer 22 having opposite first and second surfaces 22a, 22b and disposed on the carrier 21 via the first surface 22a thereof, wherein at least a cavity 220 is formed in the second surface 22b of the dielectric layer 22 to expose the bonding pads 210; and a plurality of conductive posts 26 formed in the dielectric layer 22 and positioned around a periphery of the cavity 220.

The carrier 21 can be a packaging substrate, and the dielectric layer 22 can be made of a photo imageable dielectric material. A circuit layer 25 can be formed on the second surface 22b of the dielectric layer 22 and electrically connected to the conductive posts 26.

In an embodiment, the package structure 2 further has an electronic element 28 disposed in the cavity 220 and electrically connected the bonding pads 210.

According to the present invention, a dielectric layer 22 is formed on a carrier 21, a plurality of conductive posts 26 are embedded in the dielectric layer 22 and a stack member 29 is stacked on the dielectric layer 22 and electrically connected to the conductive posts 26. As such, the present invention achieves a preferred stand-off effect between the conductive posts 26 so as to prevent bridging from occurring between the conductive posts 26.

Further, the size of the conductive posts 26 can be controlled through the through holes 260 so as to cause the conductive posts 26 to have a uniform height. Therefore, the present invention overcomes the conventional drawback of joint deviation and ensures a reliable bonding between the conductive posts 26 and conductive elements 291, thus improving the product yield.

Furthermore, since the dielectric layer 22 has a photo imageable property, the cavity 220 can be formed in the dielectric layer 22 by exposure and development, thereby simplifying the fabrication process.

The above-described descriptions of the detailed embodiments are only to illustrate the preferred implementation according to the present invention, and it is not to limit the scope of the present invention. Accordingly, all modifications and variations completed by those with ordinary skill in the art should fall within the scope of present invention defined by the appended claims.

1-5. (canceled)

6. A method for fabricating a package structure, comprising the steps of:
providing a carrier having a plurality of bonding pads and a dielectric layer having opposite first and second surfaces;
laminating the dielectric layer on the carrier via the first surface thereof, wherein the bonding pads are covered by the dielectric layer;
forming a plurality of conductive posts in the dielectric layer; and
forming at least a cavity in the second surface of the dielectric layer so as to expose the bonding pads, wherein the conductive posts are positioned around a periphery of the cavity.

7. The method of claim 6, wherein the carrier is a packaging substrate, a semiconductor chip, a wafer, an interposer, or a packaged or unpackaged semiconductor element.

8. The method of claim 6, wherein the second surface of the dielectric layer has a conductive layer used for forming the conductive posts.

9. The method of claim 6, wherein forming the conductive posts comprises:
forming a plurality of through holes penetrating the dielectric layer; and
filling a conductive material in the through holes to form the conductive posts.

10. The method of claim 6, wherein the second surface of the dielectric layer has a circuit layer electrically connected to the conductive posts.

11. The method of claim 6, wherein the dielectric layer is made of a photo imageable dielectric material.

12. The method of claim 11, wherein the cavity is formed by exposure and development.

13. The method of claim 6, further comprising disposing an electronic element in the cavity, wherein the electronic element is electrically connected to the bonding pads.

14. The method of claim 6, further comprising stacking a stack member on the second surface of the dielectric layer, wherein the stack member is electrically connected to the conductive posts.

15. The method of claim 14, wherein the stack member is a packaging substrate, a semiconductor chip, an interposer or a package.
